(19) United States
(12) Patent Application Publication
(10) Pub. No.: US 2012/0097934 A1
(43) Pub. Date: Apr. 26, 2012

(54) Organic Light Emitting Diode and Method of Fabricating the Same

(76) Inventors: Chang-Je SUNG, Gyeonggi-do (KR); Hwa-Kyung KIM, Gyeonggi-do (KR); Jeong-Kyun SHIN, Gyeonggi-do (KR); Youn-Seok KAM, Seoul (KR)

(21) Appl. No.: 13/275,697

(22) Filed: Oct. 18, 2011

(30) Foreign Application Priority Data
Oct. 25, 2010 (KR) 10-2010-0104129

(51) Int. Cl. H01L 51/50

(52) U.S. Cl. 257/40; 438/46; 257/E51.019

(57) ABSTRACT

An organic light emitting diode includes a first electrode on a substrate; a hole transporting layer on the first electrode; a light emitting material layer on the hole transporting layer; an electron transporting layer on the light emitting material layer and doped with a metal; a second electrode on the electron transporting layer; and a buffer layer between the electron transporting layer and the second electrode and using an organic material of a triphenylene skeleton including substituted or nonsubstituted heteroatom, or a substituted or nonsubstituted Pyrazino quinoxaline derivative compound.

The present invention claims the benefit of Korean Patent Application No. 10-2010-0104129, filed in Korea on Oct. 25, 2010, which is hereby incorporated by reference for all purposes as if fully set forth herein.

### BACKGROUND OF THE INVENTION

1. Field of the Invention

The present invention relates to an organic light emitting diode, and more particularly, to an organic light emitting diode and a method of fabricating the same.

2. Discussion of the Related Art

Until recently, display devices have typically used cathode-ray tubes (CRTs). Presently, many efforts and studies are being made to develop various types of flat panel displays, such as liquid crystal display (LCD) devices, plasma display panels (PDPs), field emission displays, and organic light emitting diodes (OLEDs), as a substitute for CRTs. Of these flat panel displays, OLEDs have many advantages, such as low power supply, thin profile, wide viewing angle light weight, fast response time and fabrication in a low temperature.

The OLED includes an anode, a cathode and a light emitting material layer between an anode and a cathode. When a current is applied to the anode and the cathode and a hole and an electron, which are generated from the anode and the cathode, respectively, are injected into the light emitting material layer, the hole and the electron are combined and an exciton is thus generated. Using a phenomenon that light emission is made according to a transition of the exciton from an excited state to a ground state, images are displayed.

FIG. 1 is a schematic view illustrating an OLED according to the related art, and FIG. 2 is a band diagram of the OLED according to the related art.

Referring to FIG. 1, the OLED 10 includes a substrate 12, a first electrode 14, a hole transporting layer (HTL) 18, an light emitting material layer (EML) 20, a electron transporting layer (ETL) 22, and a second electrode 26.

The first electrode 14 as an anode is an electrode for injecting a hole and is formed of indium-tin-oxide (ITO) that is a transparent metal oxide material. The second electrode as a cathode is an electrode for injecting an electron and is formed of a thin film of magnesium (Mg) and aluminum (Al). In the OLED 10 that is a top emission type, in order that a light emitted from the light emitting material layer 20 is reflected and radiates through the second electrode 26, a reflection layer 28 made of a metal such as silver (Ag) may be formed between the substrate 12 and the first electrode 14.

In the OLED 10, a hole injecting layer (HIL) 16 between the first electrode 14 and the hole transporting layer 18 and an electron injecting layer (EIL) 24 between the electron transporting layer 22 and the second electrode 26 may be further provided. The hole injecting layer 16 and the electron injecting layer 24 are formed to more efficiently inject the hole and the electron into the hole transporting layer and the electron transporting layer, respectively. The electron injecting layer 24 is made of fluorine lithium (LiF).

In the above-described OLED 10, the second electrode 26 is formed on the electron injecting layer 24 using a sputtering method with magnesium (Mg) and aluminum (Al). This may cause damage on the electron injecting layer 24 and the electron transporting layer 22, and, to prevent the problem, a buffer layer 30 is formed additionally. The buffer layer 30 is formed of an organic material, for example, copper(II)-phthalocyanine (CuPc) or zinc-phthalocyanine (ZnPc).

Referring to FIG. 2, when an anode terminal and a cathode terminal are connected to the first and second electrodes 14 and 26, respectively, and are supplied with voltages, a hole formed from the first electrode 14 is injected into the light emitting material layer 20 along highest occupied molecular orbital (HOMO) energy levels of the hole injecting layer 16 and the hole transporting layer 18, and an electron formed from the second electrode 26 is injected into the light emitting diode along lowest unoccupied molecular orbital (LUMO) energy levels of the buffer layer 30, the electron injecting layer 24 and the electron transporting layer 22. The electron and the hole injected into the light emitting material layer 20 are combined and thus forms an exciton, and a light corresponding to an energy between the hole and the electron is emitted from the exciton.

When the second electrode 26 is formed using the sputtering method, the buffer layer 30 prevents the damage on the electron injecting layer 24 and the electron transporting layer 22 but acts as an energy barrier. In other words, since the LUMO energy level of the buffer layer 30 is very higher than a work function of the second electrode 26, it is difficult for the electron formed from the second electrode 26 to move to the LUMO energy level of the buffer layer 30.

Accordingly, in order that the electrode from the second electrode 26 is injected into the light emitting material layer 20 through the buffer layer 30, the electron injecting layer 24 and the electron transporting layer 22, a higher driving voltage is needed. Further, since the electron is more difficult to inject than the hole, combination probability of the electron and the hole in the light emitting material layer 20 is reduced and light emission efficiency is thus reduced. Further, because a driving voltage is high, the light emitting material layer 20 and the hole transporting layer 18 and the electron transporting layer 22 as well that are made of an organic material suffer from much stress and degradation is thus accelerated, and this causes a problem that shortens a lifetime of the OLED 10.

### SUMMARY OF THE INVENTION

Accordingly, the present invention is directed to an organic light emitting diode and a method of fabricating the same that substantially obviates one or more of the problems due to limitations and disadvantages of the related art.

An advantage of the present invention is to provide an organic light emitting diode and a method of fabricating the same that can operate at a low voltage, improve light emission efficiency, and increase lifetime.

Additional features and advantages of the present invention will be set forth in the description which follows, and in part will be apparent from the description, or may be learned by practice of the invention. These and other advantages of the invention will be realized and attained by the structure particularly pointed out in the written description and claims hereof as well as the appended drawings.

To achieve these and other advantages and in accordance with the purpose of the present invention, as embodied and broadly described herein, an organic light emitting diode includes a first electrode on a substrate; a hole transporting layer on the first electrode; a light emitting material layer on the hole transporting layer; an electron transporting layer on the light emitting material layer and doped with a metal; a second electrode on the electron transporting layer; and a buffer layer between the electron transporting layer and the second electrode and using an organic material of a triphenylene skeleton including substituted or nonsubstituted heteroatom, or a substituted or nonsubstituted Pyrazino quinoxaline derivative compound.

In another aspect, a method of fabricating an organic light emitting diode includes forming a first electrode on a substrate; forming a hole transporting layer on the first electrode; forming a light emitting material layer on the hole transporting layer; forming an electron transporting layer on the light emitting material layer and doped with a metal; forming a buffer layer on the electron transporting layer and reducing an energy barrier; and forming a second electrode on the buffer layer.

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate embodiments of the invention and together with the description serve to explain the principles of the invention.

In the drawings:

FIG. 1 is a schematic view illustrating an OLED according to the related art;

FIG. 2 is a band diagram of the OLED according to the related art;

FIG. 3 is a schematic cross-sectional view illustrating an OLED according to an embodiment of the present invention; and

FIG. 4 is a band diagram of the OLED according to the embodiment of the present invention.

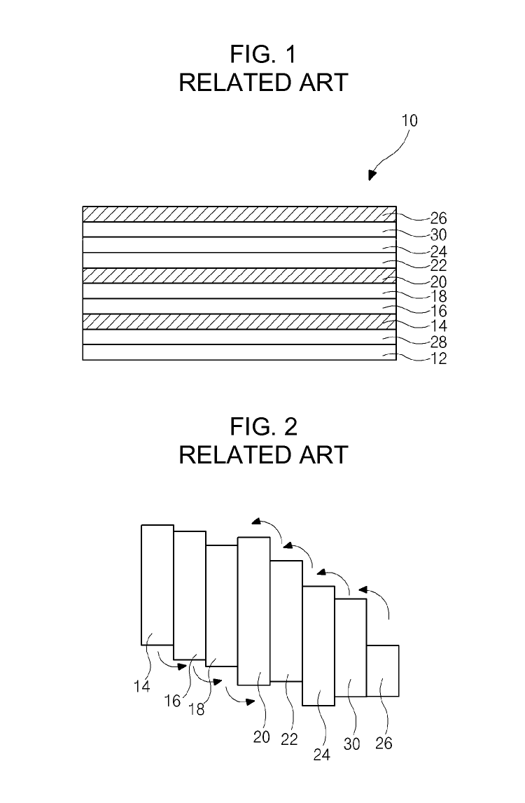

### DETAILED DESCRIPTION OF THE ILLUSTRATED EMBODIMENTS

Reference will now be made in detail to illustrated embodiments of the present invention, which are illustrated in the accompanying drawings.

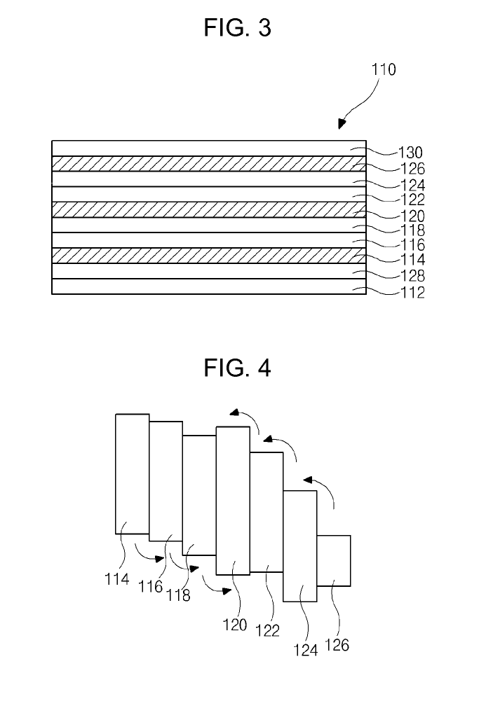

FIG. 3 is a schematic cross-sectional view illustrating an OLED according to an embodiment of the present invention, and FIG. 4 is a band diagram of the OLED according to the embodiment of the present invention.

Referring to FIG. 3, the OLED 110 according to the embodiment of the present invention includes a substrate 112, a first electrode 114, a hole transporting layer (HTL) 118, a light emitting material layer (EML) 120, an electron transporting layer 122, a buffer layer 124 and a second electrode 126. The OLED 110 may be a bottom emission type, where a light emitted from the light emitting material layer 120 radiates through the first electrode 114, or a top emission type, where the light emitted from the light emitting material layer 120 radiates through the second electrode 126, or a double-side emission type where the light emitted from the light emitting material layer 120 radiates through both of the first and second electrodes 114 and 126.

The substrate 110 may be made of glass, plastic, foil or the like, and be opaque or transparent. The first electrode 114 as an anode is an electrode for injecting a hole and may be made of a transparent metal oxide material of a high work function, such as indium-tin-oxide (ITO), indium-zinc-oxide (IZO), or indium-tin-zinc-oxide (ITZO), to make the light from the light emitting material layer 120 radiate out of the OLED 110. A reflection layer 128 made of a material such as silver (Ag) may be formed between the substrate 112 and the first electrode 114. The second electrode 126 as a cathode is an electrode for injecting an electron and may be made of a transparent conductive oxide (TCO) material such as indium-tin-oxide (ITO), zinc-tin-oxide (ZTO), indium-zinc-oxide (IZO), or indium-tin-zinc-oxide (ITZO).

The hole-transporting layer 118 and the electron transporting layer 122 function to improve light emission efficiency and reduce a driving voltage. Hole and electron from the first and second electrodes 114 and 126 and injected into the light emitting material layer 120 but not combined with each other move to their opposite electrodes. When the hole and electron enter their opposite electrodes i.e., the second and first electrodes 126 and 114, respectively, this causes reduction of combination rate of hole and electron. However, since the hole transporting layer 118 and the electron transporting layer 122 function as an electron blocking layer and a hole blocking layer that block electron and hole moving to the first and second electrodes 114 and 126, respectively, light emission efficiency can be improved.

Further, since the hole and electron from the first and second electrodes 114 and 126 are injected into the light emitting material layer 120 through the hole transporting layer 118 and the electron transporting layer 122, respectively, a driving voltage can be reduced. The hole transporting layer 118 uses NPB (N, N-di(naphthalene-1-yl)-N, N-diphenyl-benzidene), and the electron transporting layer 122 uses Alq3[tris(8-hydroxyquinolinato)aluminium], BCP or bphen.

Since the second electrode 126 is formed using a sputtering method with a transparent conductive oxide material, when the second electrode 126 is formed directly on the electron transporting layer 122, the electron transporting layer 122 may be damaged in the sputtering. Accordingly, to prevent the damage on the electron transporting layer 122, the buffer layer 126 is formed.

However, when there is an energy barrier to an extent that it is difficult for an electron formed from the second electrode 126 to easily move to the electron transporting layer, quantum efficiency may be reduced due to formation of the buffer layer 124. Accordingly, the electrode should move from the second electrode 126 to the electron transporting layer 122 via the buffer layer 123. In other words, the buffer layer 124 functions to prevent damage on the electron transporting layer 122 due to the sputtering and reduce the energy barrier between the second electrode 126 and the electron transporting layer 122 as well that is for smoothly moving the electron from the second electrode 126 to the electron transporting layer 122. A LUMO energy level of the buffer layer 124 may be set to be about 3.5 eV to about 5.5 eV.

To smoothly move the electron, the LUMO energy level of the buffer layer 124 is between a work function of the second electrode 126 and LUMO energy level of the electron transporting layer 122. For the electron from the second electrode 126 to move from a LUMO energy level of the second electrode 126 to the LUMO energy level of the buffer layer 124, an organic material of a triphenylene skeleton including a substituted or nonsubstituted heteroatom, or a substituted or nonsubstituted Pyrazino quinoxaline derivative compound, which is not much different in LUMO energy level from the second electrode 126, may be used for the buffer layer 124. The buffer layer 124 may use, for example, 1,4,5,8,9,12-hexaaza-triphenylene-2,3,6,7,10,11-hexacarbonitride expressed by a first chemical formula:

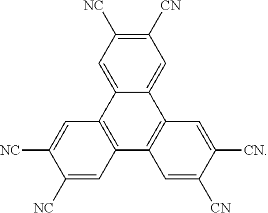

The 1,4,5,8,9,12-hexaaza-triphenylene-2,3,6,7,10,11-hexacarbonitride is a compound having a form in which triphenylene is a core, and 6 cyanide groups (—CN, —NC) are coupled to the core. Electron delocalization in a molecular structure can easily occur because of the cyanide group, and two cyanide groups located at opposite ends in a molecular structure can have different dipole moments (i.e, a positive charge and a negative charge) because of the electron delocalization of cyanide group.

When the LUMO energy level of the buffer layer 124 is lowered, a difference between the LUMO energy level of the buffer layer 124 and the LUMO energy level of the electron transporting layer 122 may relatively increase. To reduce this phenomenon, the electron transporting layer 122 is doped with a metal such that a bending of the LUMO energy level of the electron transporting layer 122 adjacent to the buffer layer 124 occurs. One of Alq3, BCP and bphen used for the electron transporting layer 122 is doped with one of lithium (Li), cesium (Cs) and aluminum (Al) in a range of about 1% to 10%.

The buffer layer is formed to have a thickness of about 50 Å to about 1000 Å. If the buffer layer 124 is formed too thin, when the second electrode 126 is formed, the electron transporting layer 122 may be damaged in the sputtering. If the buffer layer 124 is formed too thick, a driving voltage is needed to increase for an electron to pass through the buffer layer 124. Accordingly, in consideration of damage due to the sputtering and the driving voltage, the thickness of the buffer layer 124 is determined.

The OLED 110 may further include a hole injecting layer (HIL) 116 between the first electrode 114 and the hole transporting layer 118. The buffer layer 124 between the electron transporting layer 122 and the second electrode 126 can function as an electron injecting layer (EIL). The hole transporting layer 116 and the buffer layer 124 function to more efficiently inject hole and electron into the hole transporting layer 118 and the electron transporting layer 122, respectively. The hole transporting layer 124 may use CuPc (copper(II)-phthalocyanine).

The light emitting material layer 120 may use one of anthracene, PPV (poly(p-phenylenevinylene)), and PT (polythiophene). The OLED 110 may further include a capping layer 130 to reinforce optical property. By forming the capping layer 130 on the second electrode made of a transparent conductive oxide material, constructive interference according to refraction property difference between the second electrode 126 and the capping layer 128 increase, and the optical property is thus improved. An organic material, for example, Alq3 may be used for the capping layer 130.

A method of fabricating the OLED of FIG. 3 may include a step of forming the reflection layer 128 on the substrate 112, a step of forming the first electrode 114 on the reflection layer 128, a step of forming the hole injecting layer 116 on the first electrode 114, a step of forming the hole transporting layer 118 on the hole injecting layer 116, a step of forming the light emitting material layer 120 on the hole transporting layer 118, a step of the electron transporting layer 122 doped with a metal and on the light emitting material layer 120, a step of forming the buffer layer 124 on the electron transporting layer 122, a step of forming the second electrode 126 on the buffer layer 124 using the sputtering method, and a step of forming the capping layer 130 on the second electrode 126:

With reference to the band diagram of FIG. 4, a combining process of electron and hole in the OLED 110 is explained.

When an anode terminal and a cathode terminal are connected to the first and second electrodes 114 and 126, respectively, and are applied with voltages, a hole formed from the first electrode 114 is injected into the light emitting material layer 120 along HOMO energy levels of the hole injecting layer 116 and the hole transporting layer 118. An electron formed from the second electrode 126 is injected into the light emitting material layer 120 along LUMO energy levels of the buffer layer 124 and the electron transporting layer 122.

The electron from the second electrode 126 first moves to the LUMO energy level of the buffer layer 124 and second moves to the LUMO energy level of the electron transporting layer 122 from the LUMO energy level of the buffer layer 124. The electron third moves to a LUMO energy level of the light emitting material layer 120 from the LUMO energy level of the electron transporting layer 122 and is thus injected into the light emitting material layer 120. Since the electrode from the second electrode 126 is smoothly injected into the light emitting material layer 120 through the electron transporting layer 122 due to the buffer layer 124, a ratio of electron to hole is made uniform and current efficiency can thus be improved, and stress applied on the light emitting material layer 120 and the hole transporting layer 118 and the electron transporting layer 122 as well that are formed of an organic material is removed due to low driving voltages, lifetime of the OLED 110 can be extended.

Since mobility in an organic material of a hole is generally greater than that of an electron, an amount of hole is greater than that of electron. Accordingly, among electrons and holes that do not contribute to hole-electron combination in the light emitting material layer 120, holes are more likely to move to the second electrode 126 than electrons. Further, when the holes and electrons, which are formed from the first and second electrodes 114 and 126, respectively and do not contribute to hole-electron combination in the light emitting material layer 120, move to their respective opposite electrodes i.e., the second and first electrodes 126 and 114, respectively, the hole transporting layer 118 and the electron transporting layer 122 primarily block the electrons and the holes, respectively.

The Table 1 compares properties of OLEDs in first to third cases. The first case is that the buffer layer 124 is not used for the OLED 110 of FIG. 3, the second case is that a thin-film aluminum (Al) and a CuPc (copper(II)-phthalocyanine) of an organic material are used for the buffer layer 124 in the OLED 110 of FIG. 3, and the third case is that the buffer layer 124 reducing an energy barrier and the electron transporting layer 122 doped with a metal are used as shown in the OLED 110 of FIG. 3.

TABLE 1

| | | | | | | Quan- |
|---|---|---|---|---|---|---|
| | | Current | | Color | Color | tum |
| | Driving | effi- | Light | coordinate | coordinate | effi- |
| | voltage | ciency | efficiency | on x-axis | on y-axis | ciency |
| | (volt) | (Cd/A) | (lm/W) | (CIE-x) | (CIE-y) | (%) |
| 1^{st} case | 8.4 | 2.8 | 1.0 | 0.179 | 0.683 | 0.9 |
| 2^{nd} case | 8.9 | 16.0 | 5.7 | 0.274 | 0.650 | 4.5 |
| 3^{rd} case | 4.6 | 26.2 | 17.9 | 0.316 | 0.641 | 7.2 |

It is shown that the second case has the worst property that the driving voltage rises and the current efficiency, light efficiency and quantum efficiency are all lowered, compared to the first case. It is understood that the reason is that, in the second case, the aluminum and CuPc are used as the buffer layer 124 function as an energy barrier and interrupt efficient operation. Further, it is shown that the first case has the property that the driving voltage is lowered and the current efficiency, light efficiency and quantum efficiency are all excellently improved, compared to the first and second cases.

The table 2 compares properties of OLEDs in fourth and fifth cases. The fourth case is that the capping layer 130 is not used for the OLED 110 of FIG. 3, and the fifth case is that Alq3 of an organic material is used for the capping layer 130 in the OLED 110 of FIG. 3.

TABLE 2

| | | | | | | Quan- |
|---|---|---|---|---|---|---|
| | | Current | | Color | Color | tum |
| | Driving | effi- | Light | coordinate | coordinate | effi- |
| | voltage | ciency | efficiency | on x-axis | on y-axis | ciency |
| | (volt) | (Cd/A) | (lm/W) | (CIE-x) | (CIE-y) | (%) |
| 4^{th} case | 4.6 | 26.2 | 17.9 | 0.316 | 0.641 | 7.2 |
| 5^{th} case | 5.6 | 43.6 | 24.5 | 0.253 | 0.697 | 11.9 |

It is shown that the fifth case has the property that the driving voltage tends to rise a little but the current efficiency, light efficiency and quantum efficiency are all excellently improved, compared to the fourth case.

In the embodiment as described above, the buffer layer is formed between the light emitting material layer and the electron transporting layer. Accordingly, operation at a relatively low voltage is practicable. Further, ratio of hole to electron that are injected into the light emitting material layer is made uniform and light emission efficiency can thus be improved. Further, stress applied on the light emitting material and the electron and hole transporting layers is reduced and lifetime can thus increase.

It will be apparent to those skilled in the art that various modifications and variations can be made in the present invention without departing from the spirit or scope of the invention. Thus, it is intended that the present invention cover the modifications and variations of this invention provided they come within the scope of the appended claims and their equivalents.

What is claimed is:

1. An organic light emitting diode, comprising:
a first electrode on a substrate;
a hole transporting layer on the first electrode;
a light emitting material layer on the hole transporting layer;
an electron transporting layer on the light emitting material layer and doped with a metal;
a second electrode on the electron transporting layer; and
a buffer layer between the electron transporting layer and the second electrode and using an organic material of a triphenylene skeleton including substituted or nonsubstituted heteroatom, or a substituted or nonsubstituted Pyrazino quinoxaline derivative compound.

2. The diode according to claim 1, further comprising a capping layer on the second electrode and increasing an optical constructive interference.

3. The diode according to claim 2, wherein the capping layer uses Alq3.

4. The diode according to claim 1, wherein the electron transporting layer uses one of Alq3, BCP and bphen, and is doped with one of lithium (Li), cesium (Cs) and aluminum (Al) in a range of about 1% to about 10%.

5. The diode according to claim 1, wherein the buffer layer uses 1,4,5,8,9,12-hexaaza-triphenylene-2,3,6,7,10,11-hexacarbonitride.

6. The diode according to claim 1, wherein the buffer layer has a thickness of about 50 Å to about 1000 Å, and has a LUMO energy level of about 3.5 eV to about 5.5 eV.

7. The diode according to claim 1, further comprising a hole injecting layer between the first electrode and the hole transporting layer.

8. The diode according to claim 1, wherein a light emitted from the light emitting material layer radiates through the first electrode, the second electrode, or both of the first and second electrodes.

9. A method of fabricating an organic light emitting diode, the method comprising:
forming a first electrode on a substrate;
forming a hole transporting layer on the first electrode;
forming a light emitting material layer on the hole transporting layer;
forming an electron transporting layer on the light emitting material layer and doped with a metal;
forming a buffer layer on the electron transporting layer and reducing an energy barrier; and
forming a second electrode on the buffer layer.

10. The method according to claim 9, further comprising forming a capping layer on the second electrode.
